(19) United States
(12) Patent Application Publication
(10) Pub. No.: US 2018/0268887 A1
(43) Pub. Date: Sep. 20, 2018

(54) MAGNETORESISTIVE ELEMENT AND MAGNETIC MEMORY

(71) Applicant: TOSHIBA MEMORY CORPORATION, Tokyo (JP)

(72) Inventors: Masaki ENDO, Kanagawa (JP); Tadaomi Daibou, Kanagawa (JP); Shumpei Omine, Tokyo (JP); Junichi Ito, Kanagawa (JP); Akiyuki Murayama, Tokyo (JP); Takeshi Iwasaki, Mie (JP)

(73) Assignee: TOSHIBA MEMORY CORPORATION, Tokyo (JP)

(21) Appl. No.: 15/700,592

(22) Filed: Sep. 11, 2017

(30) Foreign Application Priority Data
Mar. 17, 2017 (JP) 2017-053285

(51) Int. Cl. G11C 11/16; H01L 43/08; H01L 43/10; H01L 27/22

(52) U.S. Cl. CPC G11C 11/161; H01L 43/08; H01L 43/10; G11C 11/1653; G11C 11/1675; G11C 11/1673; H01L 27/222

(57) ABSTRACT

A magnetoresistive element according to an embodiment includes: a first nonmagnetic layer; a first magnetic layer; a second magnetic layer disposed between the first nonmagnetic layer and the first magnetic layer; a second nonmagnetic layer disposed between the first magnetic layer and the second magnetic layer; a third nonmagnetic layer disposed between the second nonmagnetic layer and the second magnetic layer; and a third magnetic layer disposed between the second nonmagnetic layer and the third nonmagnetic layer, wherein elements constituting the second magnetic layer at least partially differ from elements constituting the third magnetic layer, a relative permittivity of the first nonmagnetic layer is at least 10, and the third nonmagnetic layer contains at least one element selected from the group consisting of Nb, Ta, Mo, W, Hf, Zr, Ti, Sc, V, Cr, Mn, Fe, Co, Ni, Mg, Al, Ru, Ir, Rh, Pd, Pt, Cu, Ag, and Au.

### CROSS REFERENCE TO RELATED APPLICATIONS

This application is based upon and claims the benefit of priority from the prior Japanese Patent Application No. 2017-053285, filed on Mar. 17, 2017, the entire contents of which are incorporated herein by reference.

### FIELD

Embodiments described herein relate generally to magnetoresistive elements and magnetic memories.

### BACKGROUND

The magnetic random access memory (MRAM) is constituted by the magnetic tunnel junctions (MTJs). An MTJ includes a first magnetic layer serving as the storage layer, a second magnetic layer serving as the reference layer, and a nonmagnetic layer disposed between the first and second magnetic layer. The data storage is performed by switching the magnetization direction in the first magnetic layer serving as the storage layer.

Since the MRAM has a nonvolatility, it is expected to reduce of static power consumption by replacing a volatile memory, such as dynamic random access memory (DRAM), static random access memory (SRAM). A nonvolatility is related to thermal stability in the first magnetic layer. Whereas, data writing, magnetization direction manipulation, is operated by applying a spin-polarized current, which is called a spin transfer torque (STT). In the case of a first magnetic layer with high thermal stability, writing current relatively becomes larger, which means to increase dynamic power consumption. Thus, it is a challenge to make an ideal MTJ with high thermal stability and low writing current, simultaneously.

### BRIEF DESCRIPTION OF THE DRAWINGS

FIG. 1 is a cross-sectional view showing an MTJ according to a first embodiment.

FIGS. 2A and 2B are waveform charts showing a first example of write sequences to be executed by the MTJ in the first embodiment.

FIGS. 3A and 3B are waveform charts showing a second example of write sequences to be executed by the MTJ in the first embodiment.

FIG. 4 is a cross-sectional view showing an MTJ according to a first modification of the first embodiment.

FIG. 5 is a cross-sectional view showing an MTJ according to a second modification of the first embodiment.

FIGS. 6A and 6B are cross-sectional views showing procedures for manufacturing the MTJ of the first embodiment.

FIG. 7 is a cross-section showing the relevant components of a memory cell in an MRAM according to a second embodiment.

FIG. 8 is a circuit diagram showing the relevant components of the MRAM of the second embodiment.

### DETAILED DESCRIPTION

First, we are going to describe the reason why we have done the present invention.

A storage layer that has a stacked structure constituted of a magnetic layer, a nonmagnetic metal layer, and a CoFeB layer is often adopted to increase the thermal stability. In this case, an MTJ also has a high magnetic anisotropy constant Ku and a high Gilbert damping constant. Whereas thermal stability is proportional to Ku, writing current is proportional to Gilbert damping constant. Therefore, the magnetization switching current (write current) becomes higher in this stacked structure. In a case using the spin transfer torque (STT) for magnetization switching, there is a trade-off between thermal stability and writing current.

In a single thin-CoFeB layer case, it is suggested to reduce the writing current by using voltage effect adding to current (S The magnitude of interfacial magnetic anisotropy constant KI could be controlled by applying voltage, which is mediated by changing carrier concentration and/or electro-migration at the interface of CoFeB layer and nonmagnetic material layer next to CoFeB. Writing current can be reduced if the Ku is reduced by applying voltage when data writing operates. However, the single CoFeB storage layer cannot satisfy high thermal stability.

Therefore, it is assumed that, if a voltage effect is used in a storage layer having a stacked structure to achieve a higher thermal stability, the writing current can be reduced. However, a voltage effect is an interface effect. Thus, when a voltage effect is applied in a storage layer having a stacked structure, voltage is desirably applied to both interfaces of the storage layer. However, in a case where two magnetic layers made of the same material are used in the stacked structure, the polarities of the two interfaces differ from each other, and therefore, the magnetic anisotropy at each of the two interfaces cannot be increased or reduced.

The inventors came to the idea that a high thermal stability and a low write current can be achieved with a storage layer having the structure described below. Specifically, the storage layer and nonmagnetic layers are stacked, and the signs of voltage modulations at the top and bottom interfaces of the storage layer differ from each other, so that the magnetic anisotropy at each of the two interfaces can be increased or reduced. A magnetoresistive element having such a structure will be described below as an embodiment.

A magnetoresistive element according to an embodiment includes: a first nonmagnetic layer; a first magnetic layer; a second magnetic layer disposed between the first nonmagnetic layer and the first magnetic layer; a second nonmagnetic layer disposed between the first magnetic layer and the second magnetic layer; a third nonmagnetic layer disposed between the second nonmagnetic layer and the second magnetic layer; and a third magnetic layer disposed between the second nonmagnetic layer and the third nonmagnetic layer, wherein elements constituting the second magnetic layer at least partially differ from elements constituting the third magnetic layer, a relative permittivity of the first nonmagnetic layer is at least 10, and the third nonmagnetic layer contains at least one element selected from the group consisting of Nb, Ta, Mo, W, Hf, Zr, Ti, Sc, V, Cr, Mn, Fe, Co, Ni, Mg, Al, Ru, Ir, Rh, Pd, Pt, Cu, Ag, and Au.

### First Embodiment

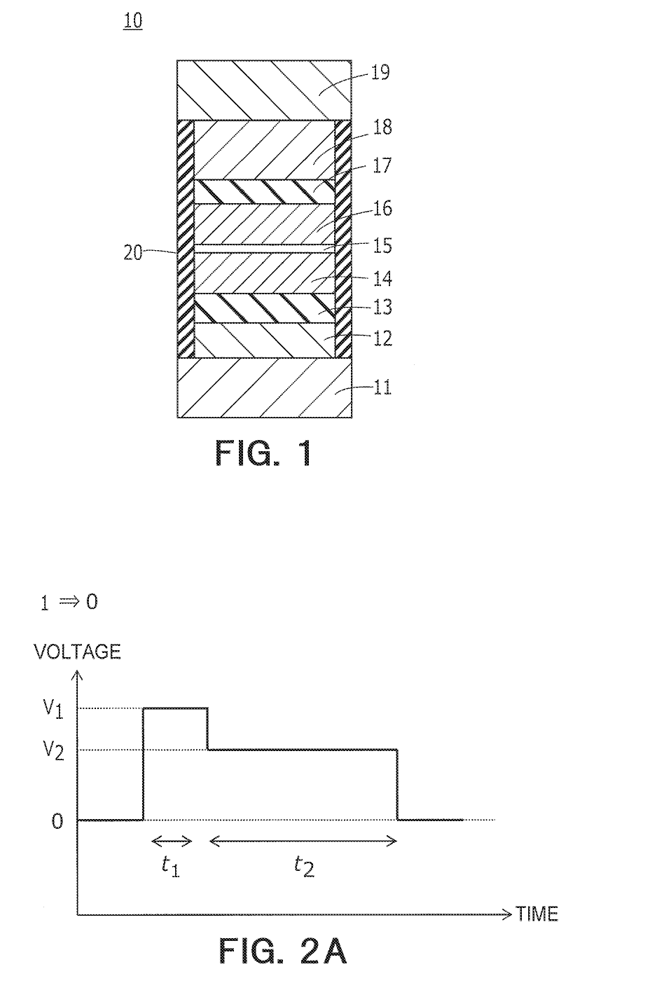

FIG. 1 shows a cross-section of a magnetoresistive element according to a first embodiment. A magnetoresistive element 10 of the first embodiment has a structure in which a lower electrode 11, a base layer (fourth nonmagnetic layer) 12, a high-dielectric nonmagnetic layer (first nonmagnetic layer) 13, a magnetic layer (second magnetic layer) 14, an amorphous nonmagnetic layer (third nonmagnetic layer) 15, a magnetic layer (third magnetic layer) 16, a nonmagnetic layer (second nonmagnetic layer) 17, a magnetic layer (first magnetic layer) 18, and an upper electrode 19 are stacked in this order. A protection layer 20 formed with an insulator is disposed on the side surfaces of a stacked structure formed with the base layer 12, the magnetic layer 14, the nonmagnetic layer 17, and the magnetic layer 18. It should be noted that the protection layer 20 is designed to cover at least the side surfaces of the nonmagnetic layer 17.

In this embodiment, the magnetic layer 14 and the magnetic layer 16 form the storage layer, and the magnetic layer 18 forms the reference layer. The storage layer has a changeable magnetization direction, and the reference layer has a fixed magnetization direction. Here, “a changeable magnetization direction” means that a magnetization direction could be switched before and after a write current is applied between the lower electrode 11 and the upper electrode 19 of the magnetoresistive element 10 (or before and after writing). Meanwhile, “a fixed magnetization direction” means that a magnetization direction have been never switched before and after a write current is applied between the lower electrode 11 and the upper electrode 19 of the magnetoresistive element 10 (or before and after writing). The magnetization directions in both of the storage and the reference layer may be parallel or normal to the direction of stacking direction. In a case where the magnetization directions are parallel to the direction of stacking, each storage and the reference layer are dominated by a perpendicular magnetic anisotropy. On the otherhand, in a normal to the direction of stacking case, dominated by in-plane magnetic anisotropy.

(Write Operation)

A write operation to be performed on the magnetoresistive element 10 in the first embodiment having the above structure is now described. The write current is applied between the lower electrode 11 and the upper electrode 19 in a direction perpendicular to the film plane, so that the magnetization of the storage layer is switched by the spin transfer torque (STT) phenomenon.

(Antiparallel to Parallel)

In a case where the magnetic layer 16 is the storage layer, the magnetic layer 18 is the reference layer, and the magnetization direction in the magnetic layer 16 and the magnetization direction in the magnetic layer 18 are antiparallel to each other (the opposite from each other), the write current is applied from the magnetic layer 16 toward the magnetic layer 18. In this case, electrons flow from the magnetic layer 18 to the magnetic layer 16 through the nonmagnetic layer 17. Electrons that are spin-polarized by passing through the magnetic layer 18 flow into the magnetic layer 16. The spin-polarized electrons that have spins in the same direction as the magnetization in the magnetic layer 16 pass through the magnetic layer 16, but the spin-polarized electrons that have spins in the opposite direction from the magnetization in the magnetic layer 16 apply a spin torque to the magnetization in the magnetic layer 16, so that the magnetization direction in the magnetic layer 16 will be switched to parallel (same direction) to the magnetization in the magnetic layer 18.

(Parallel to Antiparallel)

In a case where the magnetization direction in the magnetic layer 16 and the magnetization direction in the magnetic layer 18 are parallel to each other, on the other hand, the write current is applied from the magnetic layer 18 toward the magnetic layer 16. In this case, electrons flow from the magnetic layer 16 to the magnetic layer 18 through the nonmagnetic layer 17. Electrons that are spin-polarized by passing through the magnetic layer 16 flow into the magnetic layer 18. The spin-polarized electrons that have spins in the same direction as the magnetization of the magnetic layer 18 pass through the magnetic layer 18, but the spin-polarized electrons that have spins in the opposite direction from the magnetization in the magnetic layer 18 are reflected by the interface between the nonmagnetic layer 17 and the magnetic layer 18, and flow back into the magnetic layer 16 through the nonmagnetic layer 17. As a result, a spin transfer torque is applied to the magnetization in the magnetic layer 16 so that the magnetization direction of the magnetic layer 16 will become the opposite from the magnetization direction in the magnetic layer 18. Consequently, the magnetization direction in the magnetic layer 16 is switched, and becomes antiparallel to the magnetization direction in the magnetic layer 18.

(Voltage Effect)

Each of the above write operations is a sequence of a magnetization reversal using the conventional STT phenomenon. To reduce the write current, a voltage effect as well as the STT phenomenon is used in this embodiment. A voltage effect is an interfacial effect to modulate a magnetic anisotropy that is one of the factors to determine the retention of a device, by using an external voltage.

In a case where a voltage is applied to the magnetoresistive element 10 of this embodiment, electron accumulation and electron depletion occurs at the interface between the nonmagnetic layer 17 and the magnetic layer 16, and the interface between the nonmagnetic layer 13 and the magnetic layer 14, respectively. In this embodiment, an asymmetric structure in which the elements constituting the magnetic layer 16 at least partially differ from the elements constituting the magnetic layer 14 is formed, so that the signs of magnetic anisotropy modulations with voltage at the interface between the nonmagnetic layer 17 and the magnetic layer 16, and the interface between the nonmagnetic layer 13 and the magnetic layer 14 differ from each other.

This is because, if the stacked structure has both interfaces consisted of same materials, or if the signs of magnetic anisotropy modulations with voltage are the same in both of the interfaces, the magnetic anisotropy in one of the interfaces increases when voltage is applied, but the magnetic anisotropy in the other interface decreases. Therefore, in the whole magnetic layer, the effect to modulate magnetic anisotropies with voltage becomes smaller.

In this embodiment, on the other hand, an asymmetric structure, which means both interfaces is constituted by different material pair, is formed, and the modulation sign of the magnetic anisotropies developing from the two interfaces are the same when voltage is applied. Thus, the effect that involves voltage is enhanced.

### (Magnetization Writing Using a Voltage Effect and the Current Induced-STT, Simultaneously)

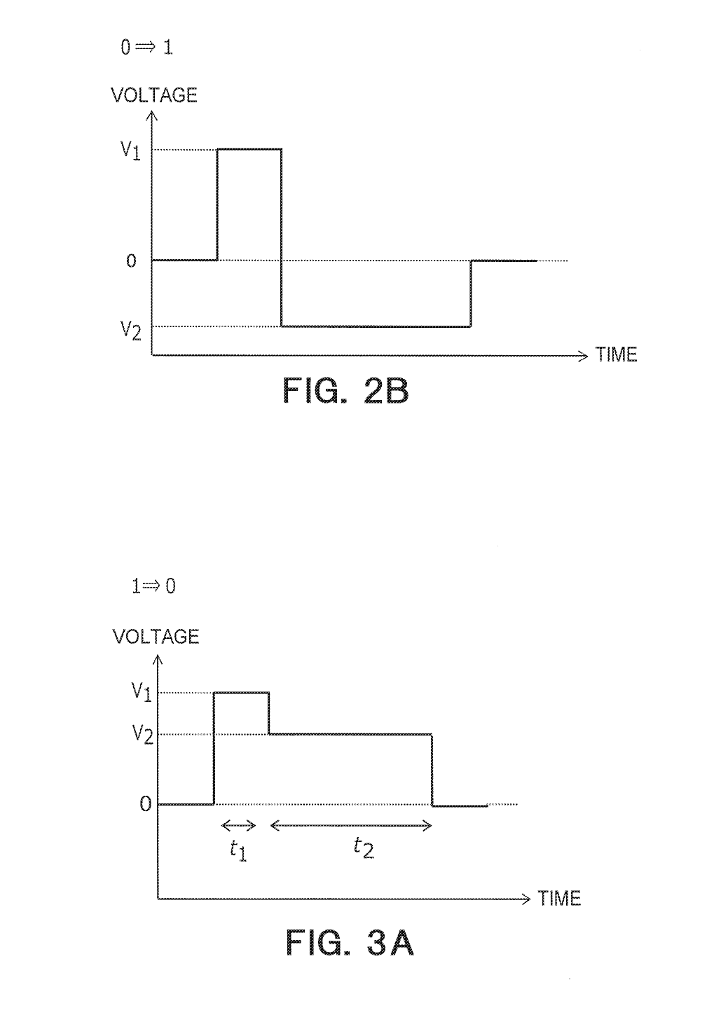

Before a write voltage compliant with the conventional STT is applied to a magnetoresistive element, a voltage having a greater absolute value than the absolute value of the write voltage to be applied is applied. FIGS. 2A and 2B show a first example of write sequences. FIG. 2A shows a write sequence in a case where the magnetization direction of the storage layer is switched from “1” to “0”. FIG. 2B shows a write sequence in a case where the magnetization direction of the storage layer is switched from “0” to “1”.

In FIG. 2A, application of a first voltage V₁ causes development of a voltage effect, which induced the reduction of magnetic anisotropies. Application of a second voltage V₂ then causes writing by the current induced-STT. As the sign of the second voltage V₂ differs from that of the first voltage V₁, writing to switch from “0” to “1”, and writing to switch from “1” to “0” become possible. As a voltage effect and the STT technique are used in combination as above, the power consumption at the time of writing becomes 1/10 or less of that of only the STT. The first voltage V₁ and the second voltage V₂ are applied to the magnetoresistive element by write circuits.

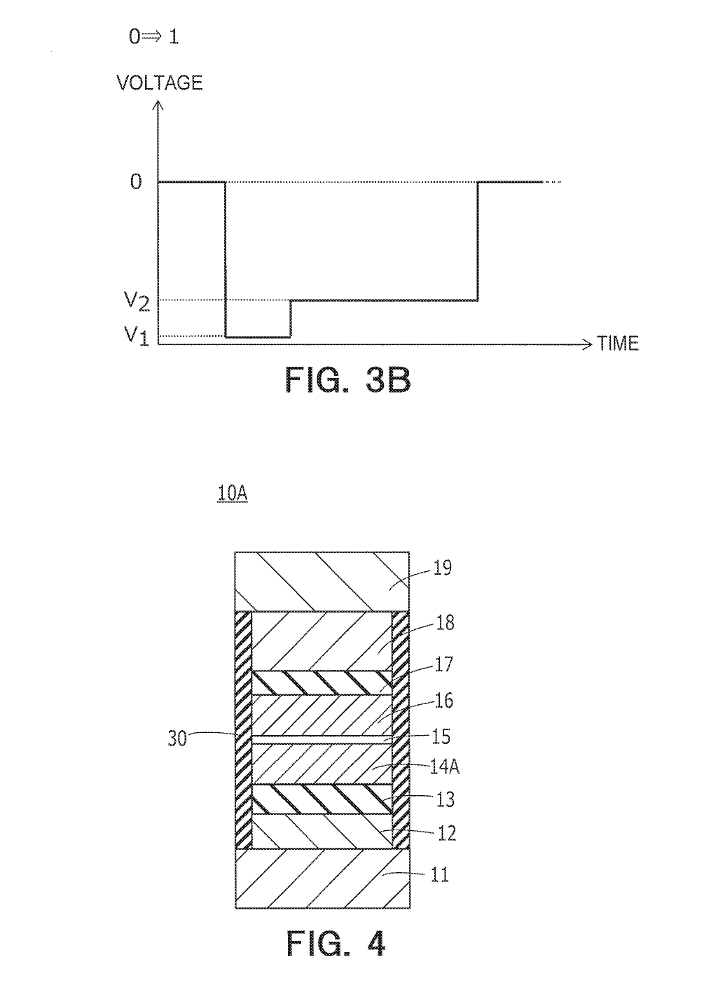

FIGS. 3A and 3B show an example where the signs of the first voltage V₁ and the second voltage V₂ are the same, as opposed to FIGS. 2A and 2B. Specifically, FIG. 3A shows a sequence in a case where the magnetization direction of the storage layer is switched from “1” to “0”. FIG. 3B shows a write sequence in a case where the magnetization direction of the storage layer is switched from “0” to “1”. In FIGS. 3A and 3B, the absolute value of the first voltage V₁ is also greater than the absolute value of the second voltage V₂. The write method illustrated in FIGS. 3A and 3B has a smaller effect to reduce magnetic anisotropies through a voltage effect than the effect to be achieved by the method illustrated in FIGS. 2A and 2B, but enables easier formation of a transistor circuit.

(Read Operation)

Reading from the magnetoresistive element 10 of the first embodiment can be performed by applying a read current between the lower electrode 11 and the upper electrode 19, and measuring the voltage between the lower electrode 11 and the upper electrode 19, for example.

Next, the materials of the respective members constituting the magnetoresistive element 10 are described.

(Lower Electrode 11)

A material that has a low electrical resistance and an excellent tolerance to diffusion is preferably used as the lower electrode 11. To achieve a lower electrical resistance, it is preferable to use Cu as the lower electrode 11, for example. To achieve a higher tolerance to diffusion, it is preferable to use Ta as the lower electrode 11, for example. Therefore, it is more preferable to use a Ta/Cu/Ta stacked structure in which a Cu layer is interposed between Ta layers.

(Base Layer 12)

The base layer 12 is a conductive layer, and is preferably formed with a material that is easily oxidized or nitrided if adhering to at least the side surfaces of the magnetic layer 16 when etching is performed to define the outer shape of the stacked structure including the nonmagnetic layer 13, the magnetic layer 14, the magnetic layer 16, and the magnetic layer 18. This material achieves insulation properties through oxidation or nitriding, and has a high dielectric breakdown voltage. For example, an amorphous layer containing at least one element selected from a first group consisting of Hf, Zr, Al, Cr, and Mg, and at least one element selected from a second group consisting of Ta, W, Mo, Nb, Si, Ge, Be, Li, Sn, Sb, and P is used as the base layer 12. An amorphous layer has excellent flatness, and can increase the crystallinity of the layer formed on the amorphous layer. In this case, the base layer 12 may be a compound alloy layer containing at least one element selected from the above first group and at least one element selected from the above second group. As used herein, a phrase referring to “at least one of” a list of items refers to any combination of those items, including a single member. As an example, “at least one of: a, b, or c” is intended to cover a, b, c, a-b, a-c, b-c, and a-b-c.”

(Nonmagnetic Layer 13)

The nonmagnetic layer 13 is preferably formed with a material that has a high permittivity, such as a material having a relative permittivity of 10 or higher, to modulate the electron state of the interface with the magnetic layer 14. For example, the nonmagnetic layer 13 is formed with at least one material selected from the group consisting of titanium oxide, zirconium oxide, hafnium oxide, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, magnesium titanium oxide, magnesium zirconium oxide, magnesium hafnium oxide, magnesium chromium oxide, manganese vanadium oxide, magnesium calcium oxide, magnesium scandium oxide, magnesium aluminum oxide, magnesium gallium oxide, magnesium iron oxide, magnesium manganese oxide, magnesium cobalt oxide, magnesium nickel oxide, magnesium zinc oxide, strontium titanium oxide, and zinc oxide. The nonmagnetic layer 13 is preferably an amorphous layer or an oriented crystal layer. The thickness of the nonmagnetic layer 13 is preferably 0.2 nm to 5.0 nm.

(Magnetic Layers 14, 16, and 18)

A ferromagnetic layer may be used as a magnetic layer 14, a magnetic layer 16, or a magnetic layer 18. A ferrimagnetic layer also may be used as a magnetic layer 14, a magnetic layer 16, or a magnetic layer 18. A CoFeB layer of 0.4 nm to 3.0 nm in thickness may be used as the storage layer, for example. A TbCoFe layer, an artificial lattice in which Co and Pt are stacked, a crystal layer having an L1₀-ordered structure formed with FePt, or the like may be used as the reference layer, for example. A CoFeB layer serving as an interfacial magnetic layer is inserted between the reference layer and the nonmagnetic layer 17, so that the spin polarizability of the Interface between the reference layer and the nonmagnetic layer 17 can be increased, and a high magnetoresistance ratio (MR ratio) can be achieved. The thickness of the CoFeB serving as the interfacial magnetic layer is preferably 0.1 nm to 5.0 nm, or more preferably, 0.4 nm to 3.0 nm.

The magnetic layers 14, 16, and 18 each preferably have a unidirectional anisotropy. The effective thickness of each of these magnetic layers is preferably 0.1 nm to 20 nm. Here, the effective thickness is the thickness of the magnetically-ordered region calculated by subtracting the thickness of the magnetically-dead layer from the entire thickness. Further, the effective thickness of each of these magnetic layers needs to be large enough to prevent the magnetic layer from becoming superparamagnetic-like order, and preferably has a thickness of 0.4 nm or greater. A Heusler alloy, such as Co₂FeAl₁₋ₓSiₓ or Co₂Mn₁₋ₓFeₓSi, can be used as the magnetic layer 16 or the magnetic layer 18. Alternatively, Fe₃Ga, Fe₃Ge, Fe₃In, Fe₃Si, Fe₃Ge, Fe₃Sn, γ-Fe, FeNx, CoNx, CoFeNx, or the like can be used as the magnetic layer 16 or the magnetic layer 18. Here, the composition rate x of FeNx, for example, does not need to match the stoichiometric proportion.

Also, a magnetic semiconductor, such as GeMn, SiCNi, SiCMn, SiCFe, ZnMnTe, ZnCrTe, BeMnTe, ZnVO, ZnMnO, ZnCoO, GaMnAs, InMnAs, InMnSb, GaMnP, GaMnN, GaCrN, AlCrN, BiFeTe, SbVTe, PbSnMnTe, GeMnTe, CdMnGeP, ZnSiNMn, ZnGeSiNMn, BeTiFeO, CdMnTe, ZnMnS, TiCoO, SiMn, or SiGeMn, may be used as the magnetic layers 14 and 18.

It is possible to adjust magnetic properties and various physical properties, such as crystalline properties, mechanical properties, and chemical properties, by adding Ti (titanium), V (vanadium), Cr (chromium), Ag (silver), Cu (copper), Au (gold), Al (aluminum), Ga (gallium), P (phosphorus), In (indium), Ru (ruthenium), Os (osmium), Re (rhenium), Ta (tantalum), B (boron), C (carbon), O (oxygen), N (nitrogen), Pd (palladium), Pt (platinum), Hf (hafnium), Zr (zirconium), Ir (iridium), W (tungsten), Mo (molybdenum), Nb (niobium), a rare-earth element, or the like to the magnetic layers 16 and 18.

(Amorphous Nonmagnetic Layer 15)

The amorphous nonmagnetic layer 15 is preferably formed with an element that does not easily mix with the magnetic layers 14, 16, and 18. The thickness of the nonmagnetic layer 15 is preferably 0.1 nm to 1.0 nm, or more preferably, 0.1 nm to 0.5 nm. The material of the nonmagnetic layer 15 contains at least one element selected from the group consisting of Nb, Ta, Mo, W, Hf, Zr, Ti, Sc, V, Cr, Mn, Fe, Co, Ni, Mg, Al, Ru, Ir, Rh, Pd, Pt, Cu, Ag, and Au. At least one element selected from the group consisting of Nb, Ta, Mo, W, Hf, Zr, Ti, Sc, V, and Al has a small boron formation energy, and accordingly, enables leaching of boron from CoFeB through a thermal treatment. At least one element selected from the group consisting of Mn, Fe, Co, and Ni enhances the exchange coupling between the magnetic layer 14 and the magnetic layer 16 through magnetic coupling. At least one element selected from the group consisting of Cr, Ru, Ir, Rh, Pd, Pt, Cu, Ag, and Au enhances the exchange interaction between the magnetic layer 14 and the magnetic layer 16. At least one element selected from the group consisting of Mg, Nb, Ta, Mo, W, Ru, Pt, Cu, Ag, and Au prevents elemental diffusion between the magnetic layer 14 and the magnetic layer 16. Hf generates a perpendicular magnetic anisotropy at an interface with a magnetic layer containing Fe.

(Nonmagnetic Layer 17)

The nonmagnetic layer 17 is formed with a nonmagnetic material, and the nonmagnetic material may be a nonmagnetic metal, a nonmagnetic semiconductor, an insulator, or the like. In a case where an insulator is used as the nonmagnetic layer 17, the nonmagnetic layer 17 serves as a tunnel barrier layer, and the magnetoresistive element 10 becomes an MTJ element. The areal resistance of the nonmagnetic layer 17 is preferably 10 or more times higher than the areal resistance of the nonmagnetic layer 13. Having such a structure, the nonmagnetic layer 17 can reduce the contribution from the parasitic resistance of the nonmagnetic layer 13, and increase the magnetoresistance change rate.

Also, a MgO layer of approximately 1 nm in thickness, for example, can be used as the nonmagnetic layer 17. In this case, a high MR ratio can be achieved. The material of the tunnel barrier layer is an oxide, a nitride, or sulfide containing at least one element selected from the group consisting of magnesium (Mg), calcium (Ca), barium (Ba), aluminum (Al), beryllium (Be), strontium (Sr), zinc (Zn), and titanium (Ti). It is particularly preferable to use an oxide. Specific examples of such oxides include MgO, AlO, ZnO, SrO, or TiO. Alternatively, the tunnel barrier layer may be a mixed crystal material formed with two or more materials selected from the group consisting of the above oxides, or may be a stacked structure formed with these materials. Examples of mixed crystal materials include MgAlO, MgZnO, MgTiO, or MgCaO. Examples of two-layer stacked structures include MgO/ZnO, MgO/AlO, TiO/AlO, or MgAlO/MgO. Examples of three-layer stacked structures include AlO/MgO/AlO or ZnO/MgO/ZnO. It should be noted that the left side of the symbol “/” indicates the upper layer, and the right side of the symbol “/” indicates the lower layer.

(Upper Electrode 19)

The upper electrode 19 not only functions as an electrode, but also is used as the mask when patterning is performed on the magnetoresistive element 10. Therefore, a material that has a low electrical resistance, a high tolerance to diffusion, and a high tolerance to etching or milling is preferably used as the upper electrode 19. For example, a Ta/Ru stacked structure or the like is used as the upper electrode 19.

(Protection Layer 20)

The protection layer 20 is formed with an insulating material containing at least one element that is the same kind as an element contained in the base layer 12. Specifically, the protection layer 20 is formed with an insulating material containing at least one element contained in the base layer 12, or at least one element selected from the group consisting of Hf, Zr, Al, Cr, and Mg, for example. The protection layer 20 is formed with a material that is the same as a material contained in the base layer 12 and is oxidized or nitrided to insulate the protection layer 20. That is, the protection layer 20 is formed with a material that is the same as a material contained in the base layer 12, and contains oxygen (O) or nitrogen (N). The oxide or the nitride forming the protection layer 20 should at least have insulation properties, regardless of its valence state.

(First Modification)

FIG. 4 shows a cross-section of a magnetoresistive element according to a first modification of the first embodiment. The magnetoresistive element 10A of the first modification has the same structure as the magnetoresistive element 10 of the first embodiment shown in FIG. 1, except that the magnetic layer 14 is replaced with a magnetic layer 14A. The magnetic layer 14A is formed with a material that has a higher magnetic anisotropy than the magnetic layer 14, and the sign of magnetic anisotropy modulation of the material with a voltage is the same the magnetic layer 14 but is the opposite of the magnetic layer 16.

The magnetic layer 14A is formed with a metal containing at least one element selected from the group consisting of Co, Fe, and Ni, or an alloy of these elements, such as Co—Pt, Co—Fe—Pt, Fe—Pt, Co—Fe—Cr—Pt, Co—Cr—Pt, Co—Pd, NiMnSb, Co₂MnGe, Co₂MnAl, Co₂MnSi, CoCrFeAl, MnGa, Mn₃Ga, Mn₃Ge, or L1₀-FeNi.

As the magnetic layer 14A is used, the retention properties of the magnetoresistive element improves, and the nonvolatile performance of the magnetoresistive element as a memory element becomes better. In this case, CoFe, CoNi, FeNi, FeV, or FeCr can be used as the magnetic layer 16. Also, a Heusler alloy, such as Co₂FeAl₁₋ₓSiₓ or Co₂Mn₁₋ₓFeₓSi, can be used as the magnetic layer 16. Alternatively, FeGax, FeGex, FeInx, FeSix, FeGex, FeSnx, FeNx, CoNx, CoFeNx, or the like can be used as the magnetic layer 16. Here, the composition rate x of FeGax, for example, does not need to match the stoichiometric proportion.

(Second Modification)

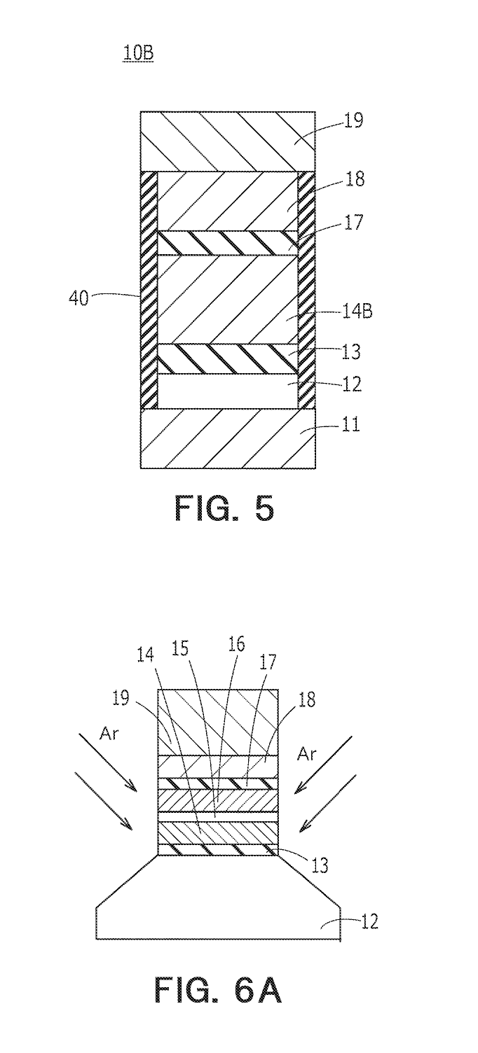

FIG. 5 shows a cross-section of a magnetoresistive element according to a second modification of the first embodiment. The magnetoresistive element 10B of the second modification has the same structure as the magnetoresistive element 10 of the first embodiment shown in FIG. 1, except that the magnetic layer 14, the nonmagnetic layer 15, and the magnetic layer 16 are replaced with a magnetic layer 14B. The magnetic layer 14B is formed with the same material as the magnetic layer 14 or the magnetic layer 14A. That is, the magnetoresistive element 10B of the second modification has a structure in which a lower electrode 11, a base layer (third nonmagnetic layer) 12, a nonmagnetic layer (first nonmagnetic layer) 13, the magnetic layer (second magnetic layer) 14B, a nonmagnetic layer (second nonmagnetic layer) 17, a magnetic layer (first magnetic layer) 18, and an upper electrode 19 are stacked in this order.

In the second modification, the nonmagnetic layer 13 is formed with MgVO, the magnetic layer 14B is formed with CoFeB, and the nonmagnetic layer 17 is formed with MgO, for example. Since the sign of magnetic anisotropy modulation with a voltage at the interface between the nonmagnetic layer 13 and the magnetic layer 14B differs from the sign of magnetic anisotropy modulation with a voltage at the interface between the magnetic layer 14B and the nonmagnetic layer 17, the voltage effect at the two interfaces is enhanced. Unlike the first embodiment and the first modification, the second modification does not involve the nonmagnetic layer 15, but has an integrated magnetic layer. Accordingly, the yield related to the characteristics between MTJ elements at the time of manufacturing of an MRAM becomes higher. As for the combination of materials, the magnetic layer 14B preferably contains Fe or Co at an atomic ratio of 80% or higher, the nonmagnetic layer 13 is preferably formed with at least one material selected from the group consisting of titanium oxide, zirconium oxide, hafnium oxide, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, magnesium titanium oxide, magnesium zirconium oxide, magnesium hafnium oxide, magnesium chromium oxide, manganese vanadium oxide, magnesium calcium oxide, magnesium scandium oxide, magnesium aluminum oxide, magnesium gallium oxide, magnesium iron oxide, magnesium manganese oxide, magnesium cobalt oxide, magnesium nickel oxide, magnesium zinc oxide, strontium titanium oxide, and zinc oxide. And the nonmagnetic layer 17 is preferably formed with an oxide, a nitride, or a sulfide containing at least one element selected from the group consisting of magnesium (Mg), calcium (Ca), barium (Ba), aluminum (Al), beryllium (Be), strontium (Sr), zinc (Zn), and titanium (Ti).

(Manufacturing Method)

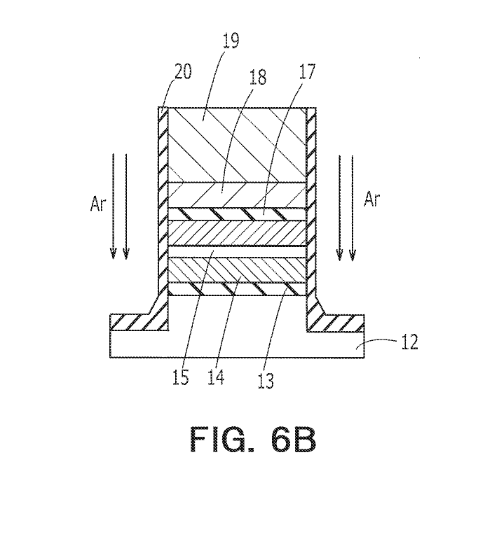

Referring now to FIGS. 6A and 6B, a method of manufacturing the magnetoresistive element 10 of the first embodiment is described.

The high-dielectric nonmagnetic layer 13, the magnetic layer 14, the amorphous nonmagnetic layer 15, the magnetic layer 16, the nonmagnetic layer 17, the magnetic layer 18, and the upper electrode 19 are stacked on the base layer 12. Patterning is then performed with first ion milling, to define the outer shape (planar shape) of the magnetoresistive element. An inert gas of Ar, Kr, Xe, or the like is used in the first ion milling. In this manufacturing method, Ar ions are used. Also, in the first ion milling, the angle of incidence of Ar ions is adjusted to a direction at approximately 50 degrees to a direction perpendicular to the upper surface of the upper electrode 19. In this manner, formation of a deposition layer on the side surfaces of the nonmagnetic layer 17 due to the ion milling can be prevented. The first ion milling is performed until the upper portion of the base layer 12 is processed.

The angle of incidence of Ar ions is then changed to a direction perpendicular to the film plane, as shown in FIG. 6B, and second ion milling is performed. In the second ion milling, the base layer 12 is further subjected to ion milling. As a result, part of the base layer 12 subjected to the ion milling with Ar ions is deposited on the side surfaces of the magnetoresistive element 10, and a deposition layer 20 is formed. The direction of incidence of ions in the second ion milling is preferably closer to the direction perpendicular to the upper surface of the upper electrode 19 than the direction of incidence of ions in the first ion milling with respect to the film plane of the magnetoresistive element 10.

As described above, each of the first embodiment and the modifications thereof can provide a magnetoresistive element that achieves a high thermal stability and enables writing with a low current.

### Second Embodiment

Next, a magnetic memory (MRAM) according to a second embodiment is described.

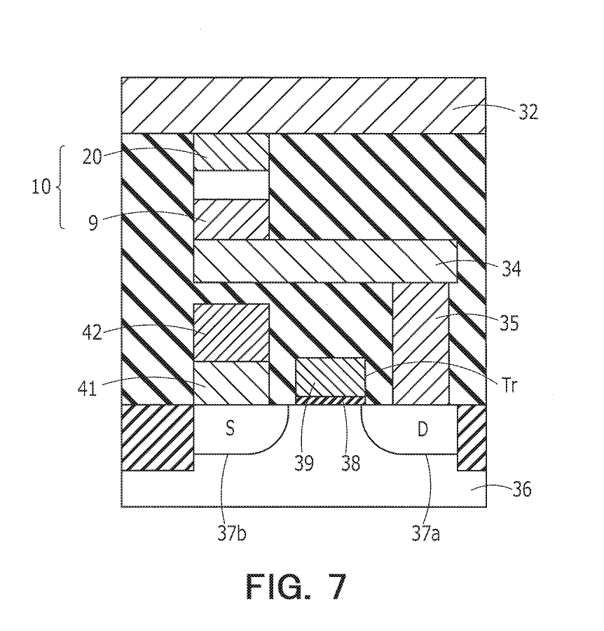

The MRAM of this embodiment includes memory cells. FIG. 7 shows a cross-section of the relevant components of a memory cell in the MRAM of this embodiment. Each memory cell includes one of the magnetoresistive elements of the first embodiment and the modifications as a memory element. In the second embodiment, an example case where the memory element is the magnetoresistive element 10 of the first embodiment is described.

As shown in FIG. 7, the upper surface of the magnetoresistive element 10 is connected to a bit line 32 via an upper electrode 20. The lower surface of the magnetoresistive element 10 is connected to a drain region 37a of source/drain regions in a surface of a semiconductor substrate 36, via a lower electrode 9, a leading electrode 34, and a plug 35. The drain region 37a, a source region 37b, a gate insulating film 38 formed on the substrate 36, and a gate electrode 39 formed on the gate insulating film 38 constitute a select transistor Tr. The select transistor Tr and the magnetoresistive element 10 constitute one memory cell in the MRAM. The source region 37b is connected to another bit line 42 via a plug 41. Alternatively, the leading electrode 34 may not be used, and the plug 35 may be provided under the lower electrode 9 so that the lower electrode 9 and the plug 35 are connected directly to each other. The bit lines 32 and 42, the lower electrode 9, the upper electrode 20, the leading electrode 34, and the plugs 35 and 41 may be formed with W, Al, AlCu, Cu, or the like.

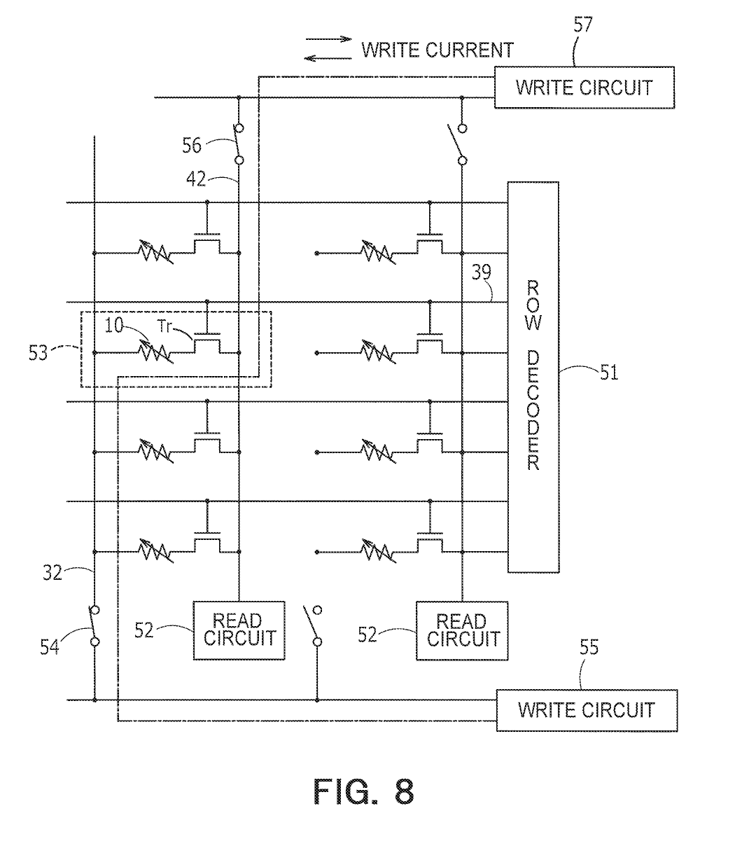

In the MRAM of this embodiment, the memory cells, one of which is shown in FIG. 7, are arranged in a matrix, to form the memory cell array of the MRAM. FIG. 8 is a circuit diagram showing the relevant components of the MRAM of this embodiment.

As shown in FIG. 8, memory cells 53 each including the magnetoresistive element 10 and the select transistor Tr are arranged in a matrix. One terminal of each of the memory cells 53 belonging to the same column is connected to the same bit line 32, and the other terminal is connected to the same bit line 42. The gate electrodes of the select transistors Tr of the memory cells 53 belonging to the same row are connected to one another by a word line 39, and are further connected to a row decoder 51.

Each bit line 32 is connected to a write circuit 55 via a switch circuit 54 of a transistor or the like. Each bit line 42 is also connected to a write circuit 57 via a switch circuit 56 of a transistor or the like. The write circuits 55 and 57 supply the write voltages V₁ and V₂, which have been described in the first embodiment, to the bit lines 32 and 42 connected to the write circuits 55 and 57.

The bit lines 42 are also connected to read circuits 52. Alternatively, the read circuits 52 may be connected to the bit lines 32. The read circuits 52 each include a sense amplifier.

At a time of writing, the switch circuits 54 and 56 connected to the write target memory cell, and the select transistor Tr are switched on, to form a current path via the target memory cell. In accordance with the information to be written, one of the write circuits 55 and 57 applies a write voltage to the corresponding bit line, so that the write current flows in the direction corresponding to the information to be written.

As for the write speed, spin-injection writing can be performed with a current having a pulse width from several nanoseconds to several microseconds.

At a time of reading, a read current that is so small as not to cause magnetization switching with the read circuit 52 is supplied to the magnetoresistive element 10 designated in the same manner as in writing. The read circuit 52 then determines the resistance state of the magnetoresistive element 10 by comparing the current value or the voltage value derived from the resistance value corresponding to the magnetization state of the magnetoresistive element 10, with a reference value.

At a time of reading, the current pulse width is preferably smaller than that at a time of writing. With this, wrong writing with the read current can be reduced. This is based on the fact that a write current with a small pulse width leads to a write current value with a large absolute value.

As described above, this embodiment can provide a magnetic memory that achieves a high thermal stability and enables writing with a low current.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A magnetoresistive element comprising:
a first nonmagnetic layer;
a first magnetic layer;
a second magnetic layer disposed between the first nonmagnetic layer and the first magnetic layer;
a second nonmagnetic layer disposed between the first magnetic layer and the second magnetic layer;
a third nonmagnetic layer disposed between the second nonmagnetic layer and the second magnetic layer; and
a third magnetic layer disposed between the second nonmagnetic layer and the third nonmagnetic layer,
wherein elements constituting the second magnetic layer at least partially differ from elements constituting the third magnetic layer,
a relative permittivity of the first nonmagnetic layer is at least 10, and
the third nonmagnetic layer contains at least one element selected from the group consisting of Nb, Ta, Mo, W, Hf, Zr, Ti, Sc, V, Cr, Mn, Fe, Co, Ni, Mg, Al, Ru, Ir, Rh, Pd, Pt, Cu, Ag, and Au.

2. The magnetoresistive element according to claim 1, wherein a sign of magnetic anisotropy modulation with a voltage at an interface between the third magnetic layer and the second nonmagnetic layer differs from a sign of magnetic anisotropy modulation with a voltage at an interface between the second magnetic layer and the first nonmagnetic layer.

3. The magnetoresistive element according to claim 1, further comprising
a fourth nonmagnetic layer that is conductive,
wherein the first nonmagnetic layer is disposed between the fourth nonmagnetic layer and the second magnetic layer, and
the fourth nonmagnetic layer is in contact with the first nonmagnetic layer.

4. The magnetoresistive element according to claim 1, wherein the first nonmagnetic layer includes at least one selected from the group consisting of titanium oxide, zirconium oxide, hafnium oxide, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, magnesium titanium oxide, magnesium zirconium oxide, magnesium hafnium oxide, magnesium chromium oxide, manganese vanadium oxide, magnesium calcium oxide, magnesium scandium oxide, magnesium aluminum oxide, magnesium gallium oxide, magnesium iron oxide, magnesium manganese oxide, magnesium cobalt oxide, magnesium nickel oxide, magnesium zinc oxide, strontium titanium oxide, and zinc oxide.

5. The magnetoresistive element according to claim 1, wherein an areal resistance of the second nonmagnetic layer is 10 or more times higher than an areal resistance of the first nonmagnetic layer.

6. A magnetoresistive element comprising:
a first nonmagnetic layer;
a first magnetic layer;
a second magnetic layer disposed between the first nonmagnetic layer and the first magnetic layer; and
a second nonmagnetic layer disposed between the first magnetic layer and the second magnetic layer,
wherein a sign of magnetic anisotropy modulation with a voltage at an interface between the second magnetic layer and the first nonmagnetic layer differs from a sign of magnetic anisotropy modulation with a voltage at an interface between the second magnetic layer and the second nonmagnetic layer.

7. The magnetoresistive element according to claim 6, further comprising
a third nonmagnetic layer that is conductive,
wherein the first nonmagnetic layer is disposed between the third nonmagnetic layer and the second magnetic layer, and
the third nonmagnetic layer is in contact with the first nonmagnetic layer.

8. The magnetoresistive element according to claim 6, wherein the first nonmagnetic layer includes at least one selected from the group consisting of titanium oxide, zirconium oxide, hafnium oxide, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, magnesium titanium oxide, magnesium zirconium oxide, magnesium hafnium oxide, magnesium chromium oxide, manganese vanadium oxide, magnesium calcium oxide, magnesium scandium oxide, magnesium aluminum oxide, magnesium gallium oxide, magnesium iron oxide, magnesium manganese oxide, magnesium cobalt oxide, magnesium nickel oxide, magnesium zinc oxide, strontium titanium oxide, and zinc oxide.

9. The magnetoresistive element according to claim 6, wherein an areal resistance of the second nonmagnetic layer is 10 or more times higher than an areal resistance of the first nonmagnetic layer.

10. A magnetic memory comprising:
first electrode and second electrode;
the magnetoresistive element according to claim 1, the magnetoresistive element being disposed between the first electrode and the second electrode; and
a write circuit configured to apply a voltage between the first electrode and the second electrode.

11. The magnetic memory according to claim 10, wherein the write circuit applies a first voltage between the first electrode and the second electrode, and applies a second voltage between the first electrode and the second electrode, the second voltage having a smaller absolute value than an absolute value of the first voltage.

12. The magnetic memory according to claim 10, wherein a sign of magnetic anisotropy modulation with a voltage at an interface between the third magnetic layer and the second nonmagnetic layer differs from a sign of magnetic anisotropy modulation with a voltage at an interface between the second magnetic layer and the first nonmagnetic layer.

13. The magnetic memory according to claim 10, wherein the first nonmagnetic layer includes at least one selected from the group consisting of titanium oxide, zirconium oxide, hafnium oxide, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, magnesium titanium oxide, magnesium zirconium oxide, magnesium hafnium oxide, magnesium chromium oxide, manganese vanadium oxide, magnesium calcium oxide, magnesium scandium oxide, magnesium aluminum oxide, magnesium gallium oxide, magnesium iron oxide, magnesium manganese oxide, magnesium cobalt oxide, magnesium nickel oxide, magnesium zinc oxide, strontium titanium oxide, and zinc oxide.

14. The magnetic memory according to claim 10, wherein an areal resistance of the second nonmagnetic layer is 10 or more times higher than an areal resistance of the first nonmagnetic layer.

15. A magnetic memory comprising:
first electrode and second electrode;
the magnetoresistive element according to claim 6, the magnetoresistive element being disposed between the first electrode and the second electrode; and
a write circuit configured to apply a voltage between the first electrode and the second electrode.

16. The magnetic memory according to claim 15, wherein the write circuit applies a first voltage between the first electrode and the second electrode, and applies a second voltage between the first electrode and the second electrode, the second voltage having a smaller absolute value than an absolute value of the first voltage.

17. The magnetic memory according to claim 15, wherein the first nonmagnetic layer includes at least one selected from the group consisting of titanium oxide, zirconium oxide, hafnium oxide, lanthanum oxide, cerium oxide, praseodymium oxide, neodymium oxide, promethium oxide, samarium oxide, europium oxide, gadolinium oxide, terbium oxide, dysprosium oxide, holmium oxide, erbium oxide, thulium oxide, ytterbium oxide, lutetium oxide, magnesium titanium oxide, magnesium zirconium oxide, magnesium hafnium oxide, magnesium chromium oxide, manganese vanadium oxide, magnesium calcium oxide, magnesium scandium oxide, magnesium aluminum oxide, magnesium gallium oxide, magnesium iron oxide, magnesium manganese oxide, magnesium cobalt oxide, magnesium nickel oxide, magnesium zinc oxide, strontium titanium oxide, and zinc oxide.

18. The magnetic memory according to claim 15, wherein an areal resistance of the second nonmagnetic layer is 10 or more times higher than an areal resistance of the first nonmagnetic layer.
